(19) United States
(12) Patent Application Publication
(10) Pub. No.: US 2026/0293108 A1
(43) Pub. Date: Sep. 24, 2026

(54) MICROELECTRONIC DEVICES INCLUDING VERTICAL CHANNEL ACCESS DEVICES, AND RELATED METHODS AND MEMORY DEVICES

(71) Applicant: Micron Technology, Inc., Boise, ID (US)

(72) Inventor: Sangwoon Lee, Meridian, ID (US)

(21) Appl. No.: 19/545,331

(22) Filed: Feb. 20, 2026

Related U.S. Application Data
(60) Provisional application No. 63/773,992, filed on Mar. 18, 2025.

(51) Int. Cl. H10B 12/00

(52) U.S. Cl. CPC H10B 12/395; H10B 12/0383

(57) ABSTRACT

A microelectronic device including a vertical channel access device that includes a semiconductor pillar. The semiconductor pillar includes a first doped region, a channel region vertically above the first doped region, and a second doped region vertically above the channel region. The vertical channel access device includes a gate electrode horizontally offset from and vertically overlapping the channel region of the semiconductor pillar and a gate dielectric material horizontally interposed between the gate electrode and the semiconductor pillar. The microelectronic device includes a dipole-forming material at a vertical position of the second doped region of the semiconductor pillar of the vertical channel access device, the dipole-forming material directly physically contacting the gate dielectric material and effectuating a fixed polarization effect at an interface of the gate dielectric material and the dipole-forming material.

### CROSS-REFERENCE TO RELATED APPLICATIONS

This application claims the benefit under 35 U.S.C. § 119(e) of U.S. Provisional Patent Application Ser. No. 63/773,992, filed Mar. 18, 2025, the disclosure of which is hereby incorporated herein in its entirety by this reference.

### TECHNICAL FIELD

This disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the density and complexity of the memory array have increased, so has the complexity of the memory devices. In some instances, horizontally oriented access devices (e.g., horizontal channel access devices) for memory cells of a memory device consume more horizontal real estate within the memory device than is desirable, reducing the memory density of the memory device.

### BRIEF DESCRIPTION OF THE DRAWINGS

FIGS. 1A through 1K illustrate simplified, vertical cross-sectional views of a microelectronic device structure at different processing stages of a method of forming a microelectronic device, according to one or more embodiments of the disclosure.

FIGS. 1L and 1M illustrate simplified, perspective views of a microelectronic device structure at different processing stages of a method of forming a microelectronic device, according to one or more embodiments of the disclosure.

FIGS. 2A through 2D are enlarged views of the area labeled “W” in FIG. 1K that show a portion of a microelectronic device structure, according to one or more embodiments of the disclosure.

FIG. 3 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, the term “sacrificial material” means and includes a material that is formed and/or employed during a fabrication process, but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic material deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

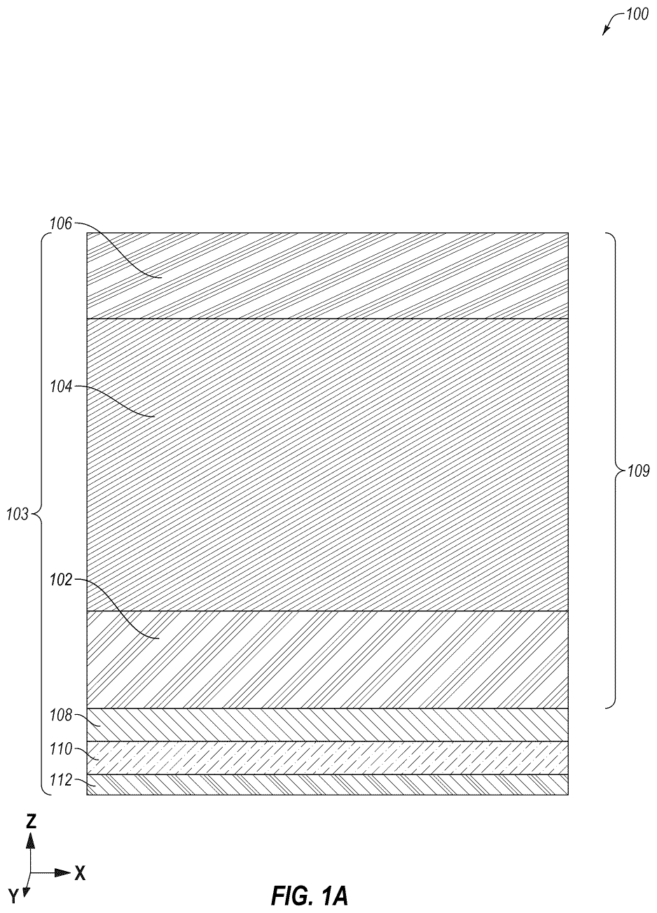

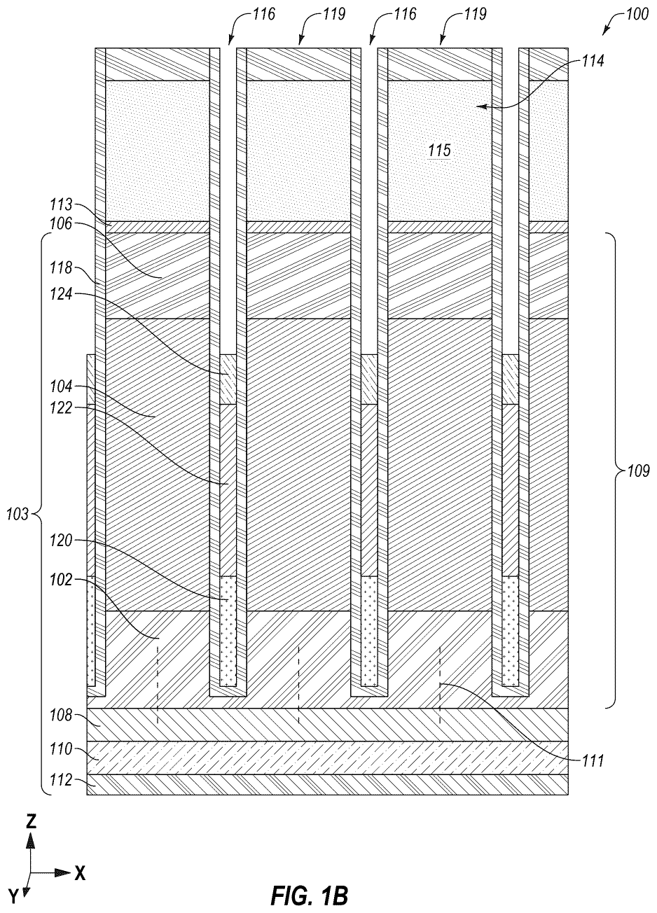

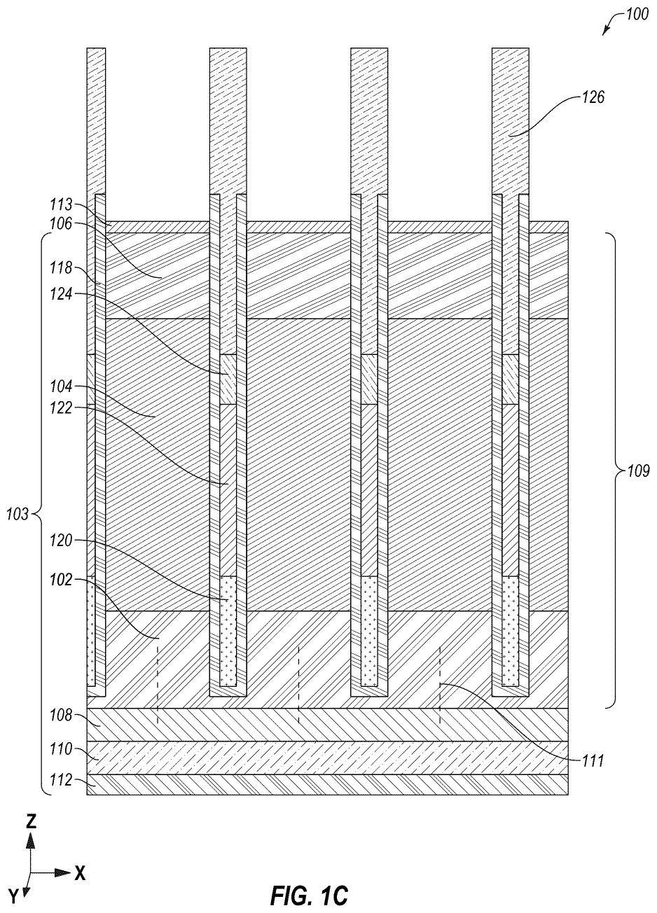

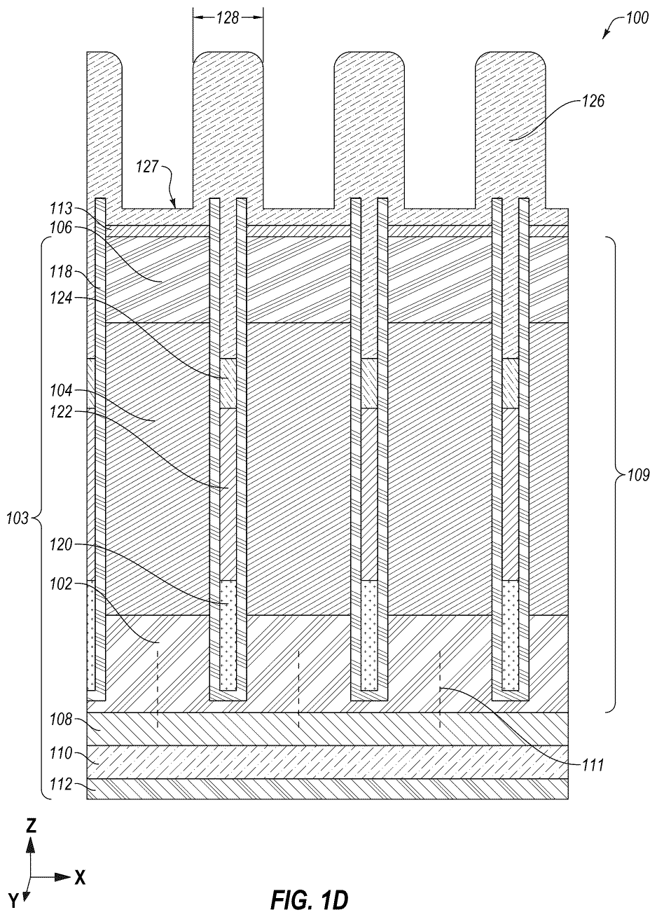

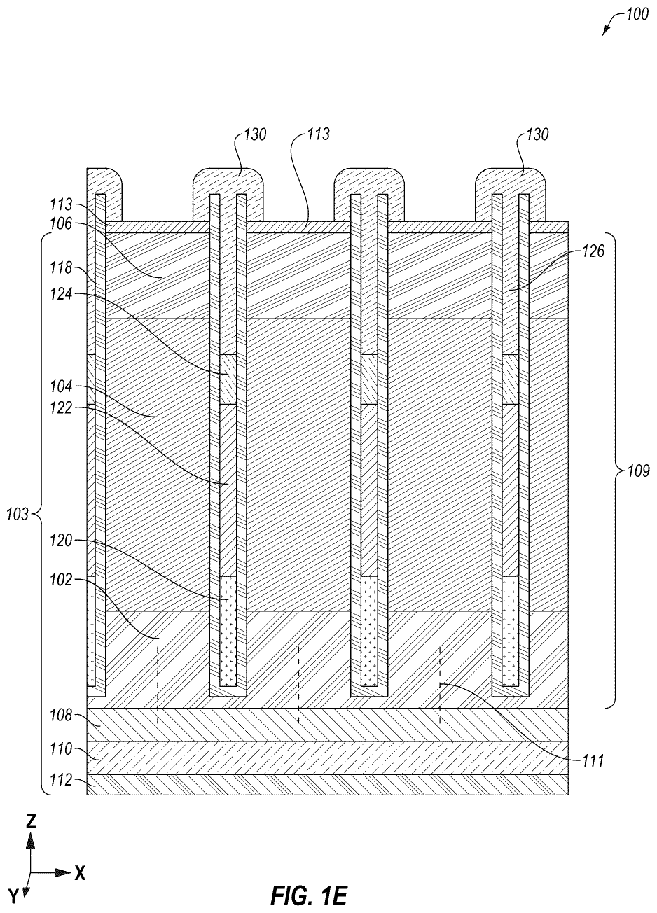

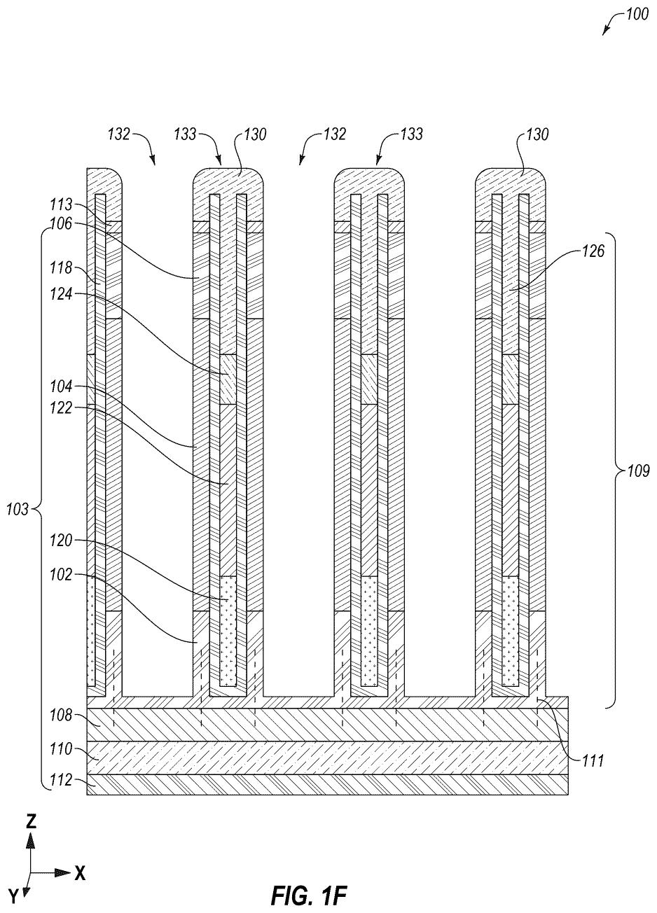

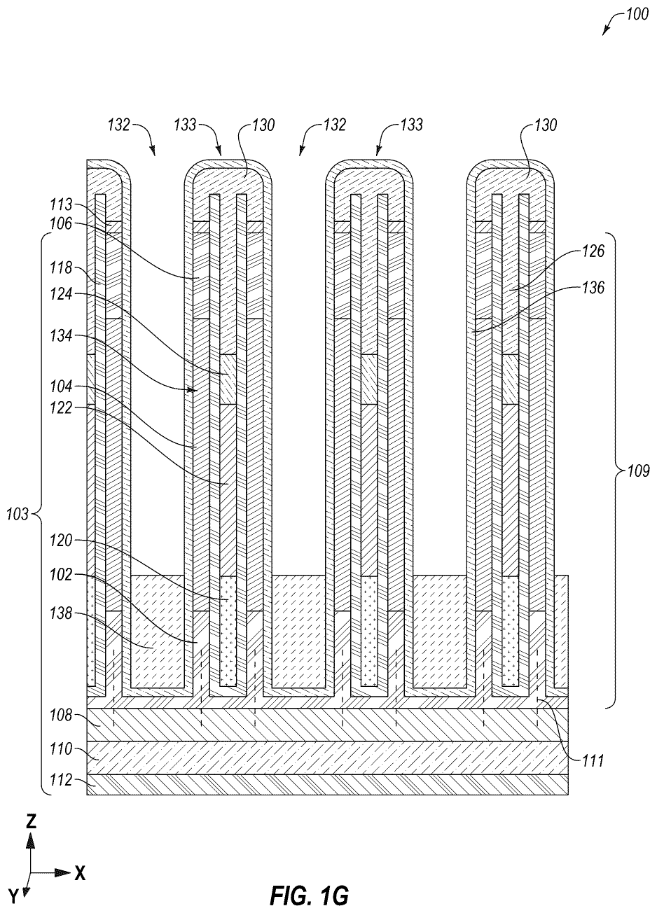

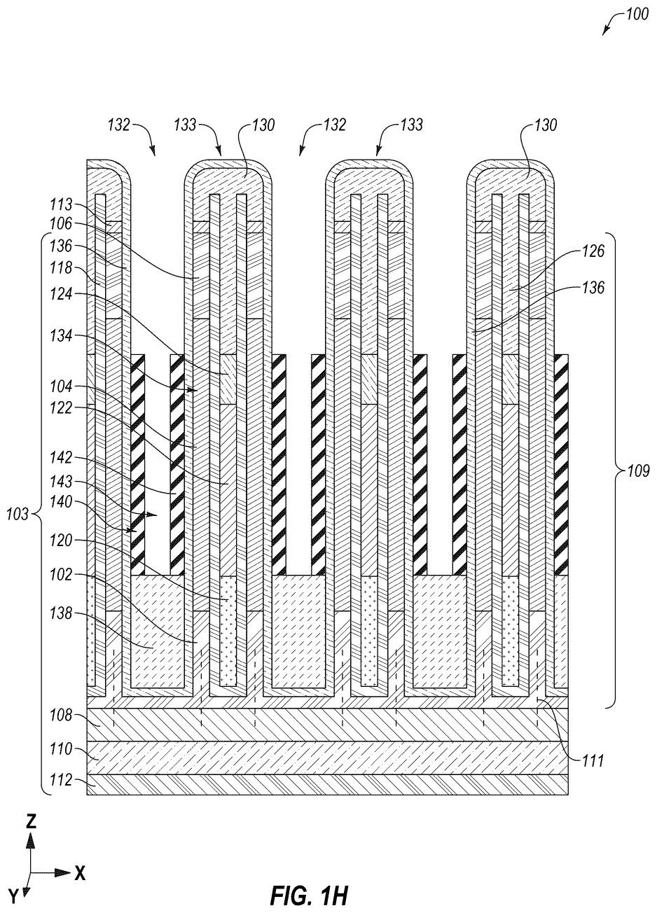

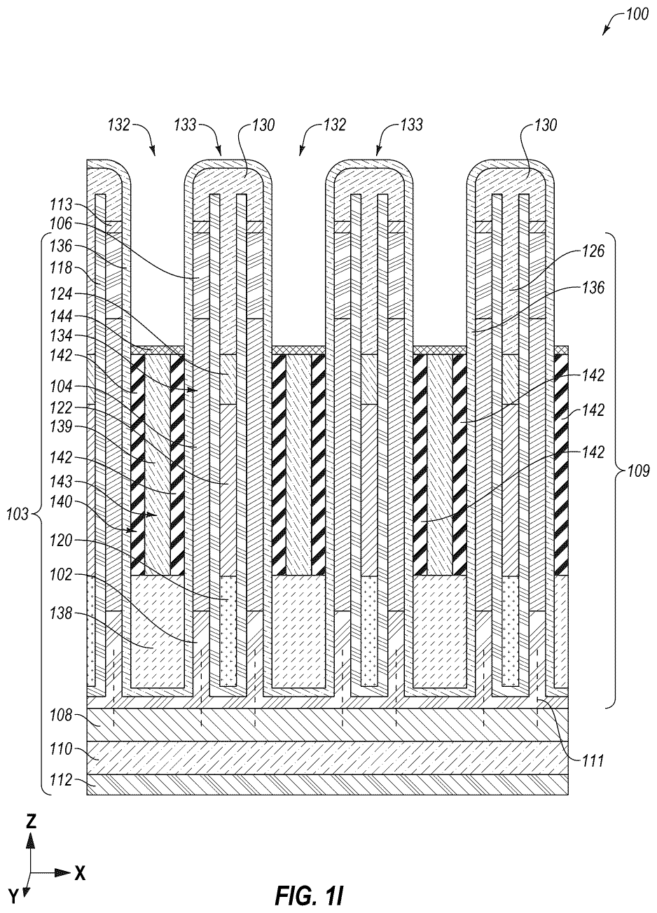

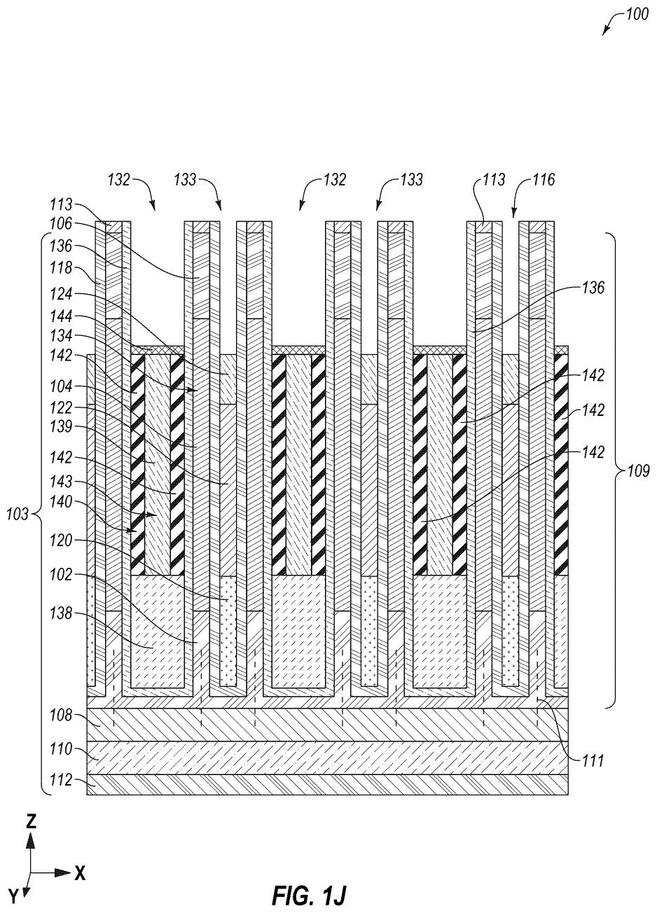

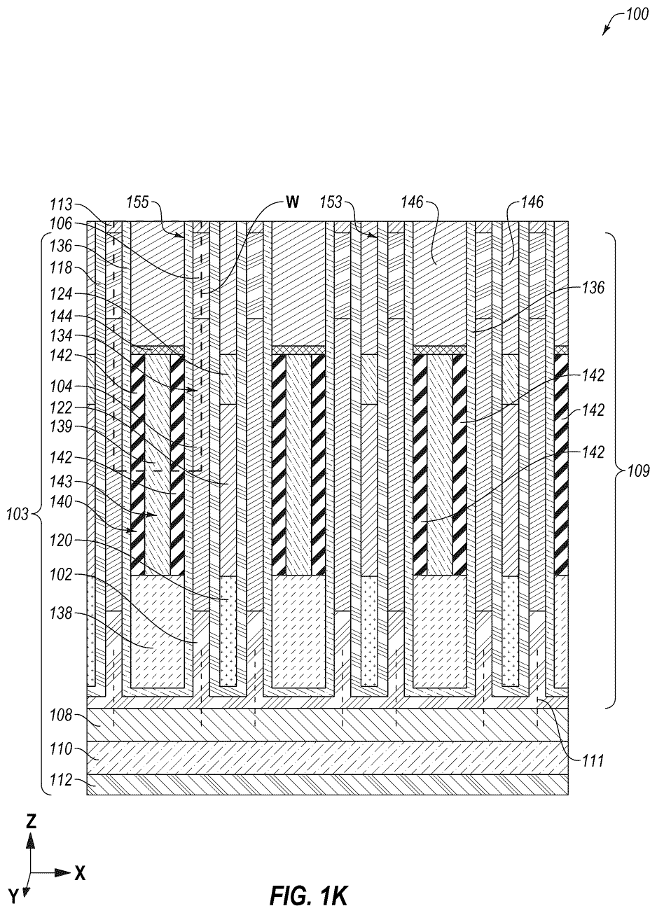

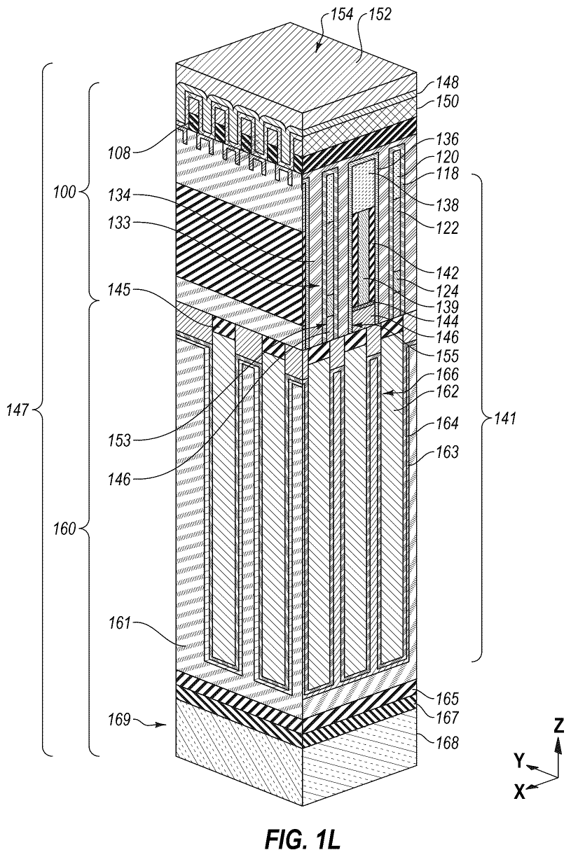

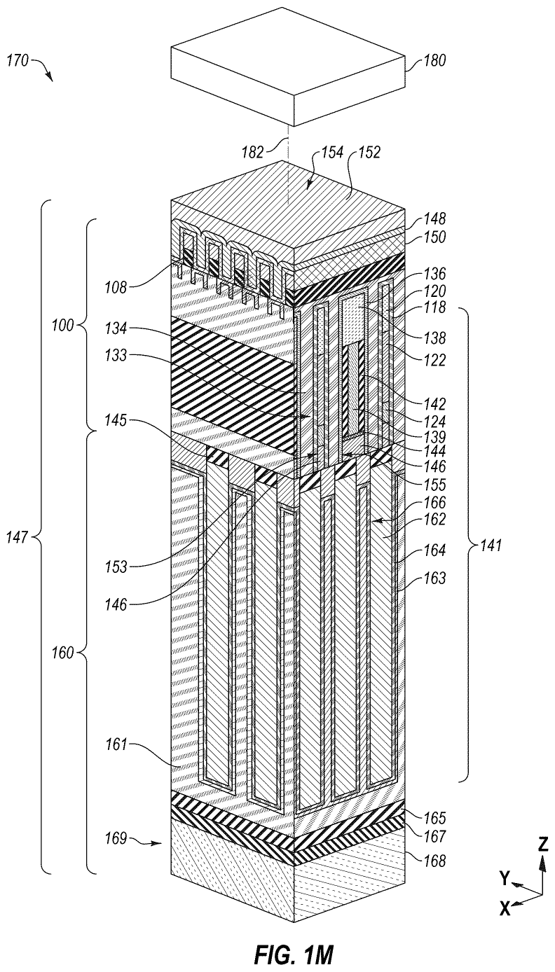

FIGS. 1A through 1K illustrate simplified, vertical cross-sectional views of a microelectronic device structure 100 at different processing stages of a method of forming a microelectronic device (e.g., a memory device, such as a DRAM device, a holographic random access memory (HRAM) device, a ferroelectric random access memory (FeRAM) device, a synchronous dynamic random access (SDRAM) device, a magnetoresistive (MRAM) device, or the like), in accordance with embodiments of the disclosure. With the description provided below, it will be readily apparent to one of ordinary skill in the art that the methods described herein may be used for forming various devices.

Referring to FIG. 1A, forming a microelectronic device structure 100 may include forming a first assembly 103. The first assembly 103 may also be referred to herein as a die or a wafer. The first assembly 103 may at least include a semiconductor material 109 (e.g., a semiconductor wafer), or a base semiconductive material on a support structure or construction upon which additional materials and structures of the microelectronic device structure 100 are formed. In some embodiments, the first assembly 103 also includes a first base structure 112 (e.g., a silicon substrate), an insulative material 110 formed on or over the first base structure 112, a digit line (DL) structures 108 (e.g., conductive material) formed on, over, or within the insulative material 110. The semiconductor material 109 may be formed on or over the DL structures 108 and the insulative material 110. In additional embodiments, the DL structures 108 are formed after the processing stage shown in FIG. 1A (e.g., after the process stage described with reference to FIG. 1K), as described in further detail below. In such embodiments, the DL structures 108 and the insulative material 110 may be replaced with an etch stop material (e.g., a semiconductive etch stop material, such as SiGe). The semiconductor material 109 may include semiconductor material, and, together with the insulative material 110, may form a silicon-over-insulator (SOI) substrate.

The semiconductor material 109 may be formed of and include silicon material, such as epitaxial silicon material. Additionally, the semiconductor material 109 may include a first doped region 102 vertically overlying the insulative material 110 and the DL structures 108 (or an etch stop material), an undoped region 104 vertically overlying the first doped region 102, and a second doped region 106 vertically overlying the undoped region 104. In some embodiments, each of the first doped region 102 and the second doped region 106 are n-type doped, such as N-type doped to an N-type dopant concentration within a range of from about 10¹⁵ cm ⁻³ to about 10²⁰ cm⁻³. In additional embodiments, one of the first doped region 102 and the second doped region 106 may be N-type doped while the other of the first doped region 102 and the second doped region 106 may be P-type doped, such as P-type doped to a P-type dopant concentration within a range of from about −10¹³ cm⁻³ to about −10¹⁸ cm⁻³. In additional embodiments, one or more of the first doped region 102 and the second doped region 106 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the semiconductor material 109. A P-type dopant may include one or more of boron, aluminum, and gallium; and an N-type dopant may include one or more of arsenic, phosphorous, antimony, and bismuth.

In some embodiments, the undoped region 104 does not include any P-type dopants or any N-type dopants. In alternative embodiments, the undoped region 104 is doped with one of the dopants described herein and become another doped region. In such embodiments, a dopant type of the undoped region 104 is different than dopant types of the first doped region 102 and the second doped region 106. For example, if the first doped region 102 and the second doped region 106 respectively include semiconductor material (e.g., epitaxial silicon) doped with at least one N-type dopant, the undoped region 104 may include the semiconductor material (e.g., epitaxial silicon) doped with at least one P-type dopant.

As is discussed in further detail below, in some embodiments, the first doped region 102 forms a drain region of a later-formed vertical channel access device (VCAD) (e.g., vertical channel transistor (VCT)), the undoped region 104 forms a channel region of the later-formed VCAD, and the second doped region 106 forms a source region of the later-formed VCAD.

Referring next to FIG. 1B, an insulative etch stop material 113 may be formed on or over the second doped region 106 of the semiconductor material 109, and a first mask material 114 may be formed on or over the insulative etch stop material 113. The first mask material 114 may have etch selectivity relative to the insulative etch stop material 113 and the first mask material 114. Thereafter, the first mask material 114 may be patterned to form first patterned masking structures 115 horizontally extending in parallel with one another along the microelectronic device structure 100. The first mask material 114 may be patterned into the first patterned masking structures 115 utilizing any suitable methodology. For instance, in some embodiments, a photoresist material is formed on or over the first mask material 114, is patterned (e.g., photoexposed and developed), and then openings formed in the patterned photoresist material are extended into the first mask material 114 to form the first patterned masking structures 115. The first patterned masking structures 115 may be removed during subsequent processing stages or may remain in a final device formed through the methods of the disclosure. The first mask material 114 may be formed of and include a dielectric material, such as a dielectric nitride material (e.g., silicide nitride).

Following formation, the first patterned masking structures 115 may be employed to form first trenches 116 (e.g., first y-axis trenches) extending vertically into the first assembly 103 and the semiconductor material 109 of the microelectronic device structure 100. The first trenches 116 may extend horizontally in parallel in a first direction (e.g., the Y-direction), and may be horizontally separated from one another in a second direction (e.g., the X-direction) orthogonal to the first direction. The first trenches 116 may have any suitable dimensions. In some embodiments, the first trenches 116 have vertical depths (e.g., vertical heights in the Z-direction) within a range of from about 100 nm to about 200 nm (e.g., about 150 nm).

In addition, in order to create the later-formed VCAD, additional trenches (e.g., x-axis trenches) may be formed to extend vertically into the first assembly 103 and the semiconductor material 109 of the microelectronic device structure 100. The additional trenches may extend horizontally in parallel in the second direction (e.g., the X-direction) perpendicular to the first direction (e.g., Y-direction) in which the first trenches 116 horizontally extend. The formation of the first trenches 116 and the additional trenches effectuates the formation of semiconductor projections 119 from the semiconductor material 109. The semiconductor projections 119 have semiconductor side surfaces that are exposed by and partially define boundaries of the first trenches 116 and the additional trenches. In some embodiments, the first trenches 116 and the additional trenches are formed using etching processes (e.g., anisotropic etching processes) that selectively remove exposed portions of the semiconductor material 109. In some embodiments, the additional trenches are formed before the first trenches 116 (e.g., using other patterned masking structures), the additional trenches are filled with dielectric material, and then the first trenches 116 are formed in the dielectric-filled, additional trenches and the remaining portions of the semiconductor material 109 using the first patterned masking structures 115 to form the semiconductor projections 119. In FIG. 1B, dashed lines 111 indicate that the first doped regions 102 of the semiconductor material 109 of the semiconductor projections 119 are in electrical communication with the DL structures 108 (if formed at the processing stage of FIG. 1A). The first doped regions 102 may be directly coupled with the DL structures 108 or may be coupled through one more additional materials as would be appreciated by one of ordinary skill in the art having the benefit of this disclosure.

With continued reference to FIG. 1B, a first dielectric liner 118 may be formed within the first trenches 116, such as on or over exposed surfaces of the semiconductor projections 119 and the first patterned masking structures 115. The first dielectric liner 118 may be formed of and include an insulative material. In some embodiments, the first dielectric liner 118 is formed of and includes silicon dioxide. In some embodiments, the first dielectric liner 118 is formed (e.g., conformally deposited) inside and outside of the first trenches 116 and portions of the first dielectric liner 118 outside of the first trenches 116 (e.g., on upper surfaces of the first mask material 114) remain. In additional embodiments, the first dielectric liner 118 is formed (e.g., conformally deposited) inside and outside of the first trenches 116 and then portions of the first dielectric liner 118 are removed (e.g., by way of CMP) while additional portions of the first dielectric liner 118 within the first trenches 116 are maintained.

In addition, a first spacer material 120 may be formed within the first trenches 116. In some embodiments, the first spacer material 120 is formed on or over exposed surfaces of the first dielectric liner 118 within the first trenches 116. The first spacer material 120 may be formed of and includes dielectric material, such as dielectric oxide material (e.g., SiO₂). The first spacer material 120 may be substantially homogeneous, or the first spacer material 120 may be heterogeneous. The first spacer material 120 may, for example, be formed of and include a stack of at least two different dielectric materials. In one or more embodiments, the first spacer material 120 is deposited within the first trenches 116 through a spin-on coating process. For instance, the first spacer material 120 may include a spin-on dielectric. Furthermore, subsequent to the spin-on coating process, the first spacer material 120 may be recessed (e.g., removed through an etching process (dry or wet etching process)) to leave portions of the first spacer material 120 at the bottoms of the first trenches 116.

With continued reference to FIG. 1B, after forming the first spacer material 120, shield gates 122 (e.g., back gates) may be formed within remainders of the first trenches 116. The shield gates 122 respectively shield later formed word line structures from cross-interference between word line structures. For example, the shield gates 122 may control electric field interference between later-formed VCADs. In some embodiments, the shield gates 122 are individually formed of and include conductive material, such as one or more of W, Ru, Mo, Ti, alloys thereof, and nitrides thereof. In some implementations, the shield gates 122 may be operably connected to a respective voltage supply at an edge of the array. The shield gates 122 may improve ION boots, IOFF control, and/or leaking management of the later formed VCADs.

The degree to which the first spacer material 120 is recessed may serve to position the shield gates 122 at a desired distance from a boundary (e.g., interface) of the first doped region 102 and the undoped region 104 of the semiconductor projections 119. For instance, the remaining portion of the spacer material 120 may space the shield gates 122 within a vertical span of the undoped region 104 and vertically offset from the boundary of the first doped region 102 and the undoped region 104. The remaining portion of the first spacer material 120 may exhibit a thickness within a range of about 30 nm and about 60 nm. For instance, the first spacer material 120 may be etched to have a thickness of about 45 nm.

As shown in FIG. 1B, in some embodiments the shield gates 122 are formed directly on upper surfaces of the remaining portions of the first spacer material 120 within the first trenches 116, and as well as directly on portions of inner sidewall surfaces of the first dielectric liner 118 formed before the first spacer material 120. In additional embodiments, an initial portion of the first dielectric liner 118 is formed within the first trenches 116, the first spacer material 120 is formed on the initial portion of the first dielectric liner 118, an additional portion of the first dielectric liner 118 is formed on exposed surfaces of the first spacer material 120 and the initial portion of the first dielectric liner 118, and then the shield gates 122 are formed on inner surfaces of the additional portion of the first dielectric liner 118. In such embodiments, part of the additional portion of the first dielectric liner 118 may vertically intervene between the shield gates 122 and the remaining portions of the first spacer material 120.

Referring still to FIG. 1B, a first insulative material 124 may be formed in the first trenches 116 over the shield gates 122. In some embodiments, the first insulative material 124 is formed of and includes silicon dioxide. In additional embodiments, the first insulative material 124 includes a material with a relatively high dielectric constant (k) (e.g., a high-k material) as compared to silicon dioxide, such as a dielectric constant greater than about 3.9 (e.g., greater than or equal to 4, such as greater than or equal to 10, greater than or equal to 20, or greater than or equal to 25). The first insulative material 124 may have a thickness within a range of from about 4 nm to about 6 nm (e.g., about 5 nm).

Referring to FIG. 1C, upper portions of the first dielectric liner 118 within the first trenches 116 (FIG. 1B) may be removed (e.g., vertically etched back), first portions of a second insulative material 126 may be formed within the first trenches 116 on or first insulative material 124 and remaining portions of the first dielectric liner 118, and then remaining portions of the first patterned masking structures 115 may be removed to expose (e.g., uncover) the insulative etch stop material 113. As shown in FIG. 1C, upper boundaries of remaining portions of the first dielectric liner 118 may vertically overlie upper surfaces of the second doped regions 106 of the semiconductor projections 119. In addition, the first portions of the second insulative material 126 may cover inner side surfaces and upper surfaces of the remaining portions of the first dielectric liner 118. The second insulative material 126 may be formed of and include dielectric material having etch selectivity relative to the semiconductor material 109 and the first dielectric liner 118. In some embodiments, the second insulative material 126 is formed of and includes dielectric nitride material (e.g., silicon nitride).

Referring next to FIG. 1D, an additional portion of the second insulative material 126 may be formed (e.g., conformally deposited) over and between the first portions of the second insulative material 126 formed in the processing stage previously described with reference to FIG. 1C. The additional portion of the second insulative material 126 may form projecting portions 127 of the second insulative material 126 individually having width 128 that horizontally spans in the X-direction completely across one of the shield gates 122 and partially across two (2) of the semiconductor projections 119 horizontally neighboring (e.g., flanking) the one of the shield gates 122 in the X-direction.

Referring to FIG. 1E, portions of the second insulative material 126 formed at the processing stage described with reference to FIG. 1D (including the projecting portions 127 thereof) may be removed (e.g., etched) to form dielectric capping structures 130 (e.g., dielectric nitride capping structures). The dielectric capping structures 130 may respectively be formed on or over upper surfaces of the first insulative material 124 within a horizonal area of individual first trench 116 (FIG. 1B), as well as on or over upper surfaces of the insulative etch stop material 113 and upper portions (e.g., upper surfaces, upper portions of sidewalls) of the remaining portions of first dielectric liner 118. Portions of an individual dielectric capping structure 130 vertically overlie (e.g., in the Z-direction) and horizontal overlap (e.g., in the Y-direction and the X-direction) an individual shield gate structure 122 and at least two (2) semiconductor projections 119 horizontally neighboring (e.g., flanking) the one of the shield gates 122 in the X-direction.

Referring to FIG. 1F, the dielectric capping structures 130 may be employed as masking structures to form second trenches 132 vertically extending through the semiconductor projections 119 (FIG. 1E) to form semiconductor pillars 133 from remaining portions of the semiconductor projections 119 (FIG. 1E). In some embodiments, the second trenches 132 may be formed using an etching process (e.g., an anisotropic etching process) that removes portions of the semiconductor material 109 of the semiconductor projections 119 (FIG. 1E) not projected by the dielectric capping structures 130. Each of the semiconductor pillars 133 may respectively include the first doped region 102, the undoped region 104, and the second doped region 106 of the semiconductor material 109.

Referring to FIG. 1G, a second dielectric liner 136 (also referred to herein as a “gate dielectric material”) may be formed (e.g., conformally deposited) on exposed surfaces of the semiconductor pillars 133 and the dielectric capping structures 130. The second dielectric liner 136 may be formed of and include insulative material. In some embodiments, the second dielectric liner 136 is formed of and includes silicon dioxide. In some embodiments, the second dielectric liner 136 is formed (e.g., conformally deposited) inside and outside of the second trenches 132, and portions of the second dielectric liner 136 outside of the second trenches 132 are maintained. In additional embodiments, the second dielectric liner 136 is formed (e.g., conformally deposited) inside and outside of the second trenches 132, and then portions of the second dielectric liner 136 outside of the second trenches 132 are removed (e.g., by way of CMP) while additional portions of the second dielectric liner 136 within the second trenches 132 are maintained. The second dielectric liner 136 may have a thickness within a range of from about 4 nm to about 6 nm (e.g., about 5 nm).

Following the formation of the second dielectric liner 136, remaining portions of the second trenches 132 may be partially filled within a second spacer material 138. In one or more embodiments, the second spacer material 138 is deposited within the second trenches 132 through a spin-on coating process. For instance, the second spacer material 138 may include a spin-on dielectric. Furthermore, subsequent to the spin-on coating process, the second spacer material 138 may be recessed (e.g., removed through an etching process (dry or wet etching process)) to leave only portions of the second spacer material 138 proximate the bottoms of the second trenches 132. In some embodiments, the second spacer material 138 is formed of and includes dielectric oxide material, such as SiOₓ (e.g., SiO₂). The second spacer material 138 may be substantially homogeneous, or the second spacer material 138 may be heterogeneous. The second spacer material 138 may, for example, be formed of and include a stack of at least two different dielectric materials.

The degree to which the second spacer material 138 is recessed may serve to position the later-formed gate electrodes (e.g., word lines) a desired distance from the boundary (e.g., interface) of the first doped region 102 and the undoped region 104 of the semiconductor pillars 133. For instance, the remaining portion of the second spacer material 138 may space the later-formed gate electrodes within a vertical span of the undoped region 104 and vertically offset from the boundary of the first doped region 102 and the undoped region 104. The remaining portion of the second spacer material 138 may exhibit a thickness within a range of about 30 nm and about 60 nm. For instance, the second spacer material 138 may be etched to have a thickness of about 45 nm.

Referring to FIG. 1H, gate electrode material 140 may be formed (e.g., conformally deposited) at least within the second trenches 132 (e.g., inside and outside of the second trenches 132), and then portions of the gate electrode material 140 may be removed (e.g., anisotropically etched) to form gate electrodes 142 (e.g., gate structures) within the second trenches 132. Within the second trenches 132, the gate electrodes 142 are vertically positioned on or over the second spacer material 138. Portions of the second dielectric liner 136 (e.g., gate dielectric material) vertically extend along the gate electrodes 142 and are horizontally interposed in the X-direction between the semiconductor pillars 133 and the gate electrodes 142. The gate electrodes 142 may respectively vertically overlap the undoped regions 104 (e.g., channel regions) of the semiconductor pillars 133. As shown in FIG. 1H, an individual second trenches 132 may include two (2) of the gate electrodes 142 formed therein. The gate electrodes 142 may comprise portions of word line (WL) structures within the second trenches 132. The gate electrode material 140 (and, hence, the gate electrodes 142) may be formed of and include conductive material, such as one or more of tungsten (W), ruthenium (Ru), molybdenum (Mo), titanium (Ti), alloys thereof, and nitrides thereof.

Still referring to FIG. 1H, within the second trenches 132, the gate electrodes 142 may be horizontally separated from one another in the X-direction by remaining, unfilled portions of the second trenches 132, shown in FIG. 1H as gaps 143. An individual gap 143 is horizontally interposed between two (2) of the gate electrodes 142 and vertically extends along the gate electrodes 142. Lower boundaries of the gap 143 may be defined by upper surfaces of the second spacer material 138 within the second trenches 132.

The formation of the gate electrodes 142 effectuates the formation of vertical channel access devices 134 and may respectively include one of semiconductor pillars 133, one of the gate electrodes 142 horizontally neighboring (e.g., in the X-direction) the one of the semiconductor pillars 133, and a portion of the second dielectric liner 136 horizontally interposed (e.g., in the X-direction) between the one of the semiconductor pillars 133 and the one of the gate electrodes 142. For an individual vertical channel access device 134, the semiconductor pillar 133 thereof may define a drain region (e.g., the first doped region 102), a source region (e.g., the second doped region 106), and a channel region (e.g., the undoped region 104) vertically interposed between the source region and the drain region. The gate electrode 142 of the vertical channel access device 134 vertically overlaps (e.g., within a vertical extent in the Z-direction) of the channel region (e.g., the undoped region 104) of the semiconductor pillar 133. The vertical channel access devices 134 may be arranged in an array including rows of the vertical channel access devices 134 horizontally extending in parallel in the X-direction, and columns of the vertical channel access devices 134 horizontally extending in parallel in the Y-direction orthogonal to the X-direction. The gate electrodes 142 may comprise portions of WL structures within the second trenches 132 and respectively shared by multiple (e.g., a column) of the vertical channel access devices 134.

Referring next to FIG. 1I, isolation material 139 may be formed within the second trenches 132 to fill (e.g., substantially fill) the gaps 143 (FIG. 1H) between the gate electrodes 142. Within an individual second trench 132, the isolation material 139 is horizontally interposed between two (2) of the gate electrodes 142 and vertically extends along the gate electrodes 142. Lower boundaries of the isolation material 139 may be at or proximate lower boundaries of the gate electrodes 142, and upper boundaries of the isolation material 139 may be at or proximate upper boundaries of the gate electrodes 142. In addition, following the formation of the isolation material 139, dielectric material 144 may be formed within the second trenches 132 and on or over the isolation material 139 and the gate electrodes 142. The dielectric material 144 may partially (e.g., less than completely) fill a remaining (e.g., unfilled) portion of the second trenches 132. The isolation material 139 and the dielectric material 144 may respectively be formed of and include insulative material and may have substantially the same or different material compositions than one another. In some embodiments, the isolation material 139 and the dielectric material 144 are respectively formed of and include dielectric oxide material, such as SiOₓ (e.g., SiO₂).

Referring next to FIG. 1J, material from the top portion of the first assembly 103 may be removed down to approximately to upper boundaries of the insulative etch stop material 113. The removal process (e.g., CMP process) may remove upper portions of the dielectric capping structures 130 (FIG. 1I), the first dielectric liner 118, and the second dielectric liner 136. Additionally, remaining portions of dielectric capping structures 130 (FIG. 1I) may be removed (e.g., etched away) from horizontal areas of the first trenches 116 to expose side surfaces (e.g., outer sider surfaces) of the first dielectric liner 118 and upper surfaces of the first insulative material 124 within the horizontal areas of the first trenches 116.

Referring next to FIG. 1K, a dipole-forming material 146 (also referred to as a “polarization-inducing material” or an “interface-tuning material”) may be formed (e.g., deposited) within unfilled portions of the first trenches 116 (FIG. 1J) and the second trenches 132 (FIG. 1J) of the microelectronic device structure 100. Within horizontal areas of the first trenches 116 (FIG. 1J), the dipole-forming material 146 may extend (e.g., horizontally and vertically extend) across and physically contact the first dielectric liner 118 at first interfaces 153. The dipole-forming material 146 may also be formed on or over the first insulative material 124 within the horizontal areas of the first trenches 116 (FIG. 1J). In addition, within horizontal areas of the second trenches 132 (FIG. 1J), the dipole-forming material 146 may extend (e.g., horizontally and vertically extend) across and physically contact the second dielectric liner 136 at second interfaces 155. The dipole-forming material 146 may also be formed on or over the dielectric material 144 within the horizontal areas of the second trenches 132 (FIG. 1J).

The dipole-forming material 146 may be formed of and include at least one material that creates a first electric dipole at the first interfaces 153 between the dipole-forming material 146 and the first dielectric liner 118 and that creates a second electric dipole at the second interfaces 155 between the dipole-forming material 146 and the second dielectric liner 136. The electric dipoles may, for example, be effectuated due to differences in electric properties of the dipole-forming material 146 relative to those of the first dielectric liner 118 and the second dielectric liner 136, such as one or more of electronegativity, band alignment, and oxygen vacancy behavior (without limitation).

In some embodiments, the dipole-forming material 146 is formed of and includes at least one material having a relatively higher dielectric constant (k) than material(s) of the first dielectric liner 118 and the second dielectric liner 136. The dipole-forming material 146 may, for example, be formed of and include a high-k material (a material having a relatively high dielectric constant (k) as compared to silicon dioxide, such as a dielectric constant greater than about 3.9, greater than or equal to 4, greater than or equal to 10, greater than or equal to 20, or greater than or equal to 25) that creates a fixed polarization effect at the first interfaces 153 and the second interfaces 155. The fixed polarization effect may result in a net positive charge on the dipole-forming material 146 sides of the first interfaces 153 and the second interfaces 155. The fixed polarization effect may mimic the effect of a fixed charge at the first interfaces 153 and the second interfaces 155 due to the localized positive charge on the dipole-forming material 146 sides of the first interfaces 153 and the second interfaces 155. The fixed polarization effect at the first interfaces 153 and the second interfaces 155 is referred to herein as an “effective fixed charge.” In some embodiments, the dipole-forming material 146 is configured such that an effective fixed charge density at the first interfaces 153 and the second interfaces 155 is within a range of from about 1×10¹⁰ charges (C) per square centimeter (cm²) (C/cm²) to about 1×10¹⁴ C/cm². The effective fixed charge density may result from the positive side of a dipole formed by polarization between the dipole-forming material 146 and the first dielectric liner 118 and the second dielectric liner 136 at the first interfaces 153 and the second interfaces 155, though contributions from defects may also play a role.

By way of non-limiting example, the dipole-forming material 146 may be formed of and include one or more of lanthanum oxide, zirconium oxide, aluminum oxide, titanium oxide, and hafnium oxide. The dipole-forming material 146 may be substantially homogeneous, or the dipole-forming material 146 may be heterogeneous. The dipole-forming material 146 may, for example, be formed of and include a stack of at least two different positively charged materials. In some embodiments, the dipole-forming material 146 is formed of and includes lanthanum oxide (La₂O₃). In some such embodiments, the first dielectric liner 118 and the second dielectric liner 136 are each formed of and include SiO₂, such that the first interfaces 153 are first La₂O₃/SiO₂ interfaces and the second interfaces 155 are second La₂O₃/SiO₂ interfaces. Without being bound to a particular theory, for La₂O₃/SiO₂ interfaces, since La₂O₃ tends to have a more ionic character as compared to the covalent nature of SiO₂, where these oxides interact, oxygen atoms (which are relatively highly electronegative) may shift slightly or bond differently due to mismatch in lattice structures or coordination environments. In La₂O₃, oxygen is coordinated with lanthanum (which has relatively low electronegativity); while in SiO₂, oxygen is bonded to silicon, which is more electronegative than lanthanum (but less so than oxygen). For an individual first interface 153 or an individual second interface 155, this difference may create a dipole moment where the oxygen ions are partially displaced toward the SiO₂ side (first dielectric liner 118 side or second dielectric liner 136 side), leaving a net positive charge on the La₂O₃ side (dipole-forming material 146 side).

During use and operation of a microelectronic device including the microelectronic device structure 100, the dipole-forming material 146 in the OFF state current (I_{OFF}) of the vertical channel access devices 134 “can be lowered” relative to conventional configuration. For example, the I_{OFF} may be lowered while the ON state current (I_{ON}) of the vertical channel access devices 134 is the same or even higher. As a result, the performance of the vertical channel access devices 134 may be enhanced relative to conventional configurations.

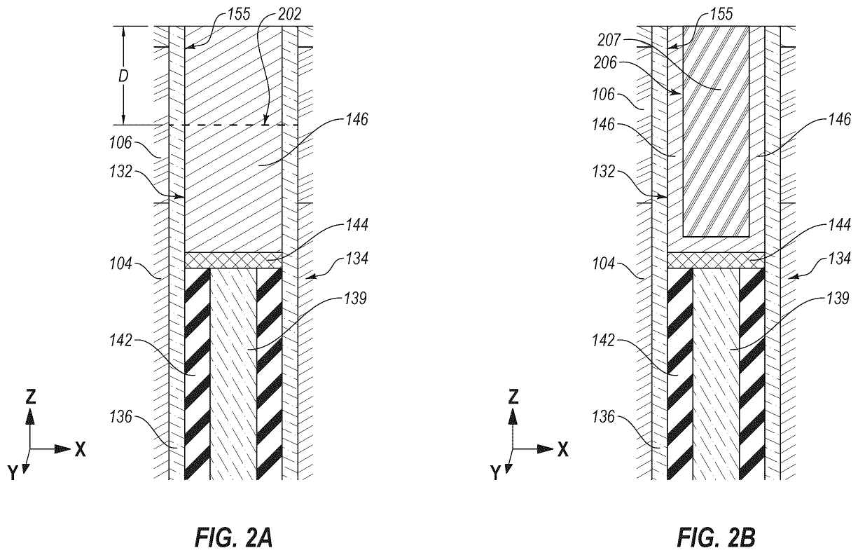

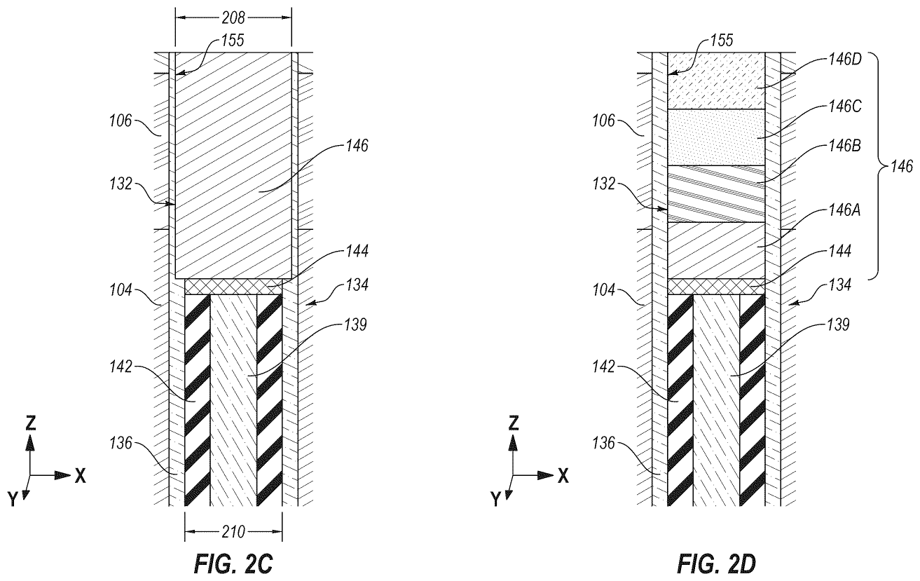

Still referring to FIG. 1K, in some embodiments, the dipole-forming material 146 is formed to substantially fill portions of the first trench 116 (FIG. 1J) and the second trenches 132 (FIG. 1J) that are unfilled following the processing stage previously described with reference to FIG. 1J. For example, the dipole-forming material 146 may be formed within the unfilled portions of the first trench 116 (FIG. 1J) and the second trenches 132 (FIG. 1J) as a bulk fill material. In additional embodiments, the dipole-forming material 146 is formed within unfilled portions of the first trench 116 (FIG. 1J) and the second trenches 132 (FIG. 1J) as a liner structure, with additional material(s) filling in remainders of the first trench 116 (FIG. 1J) and the second trenches 132 after the formation of the dipole-forming material 146. For example, the additional material may be additional dielectric material (e.g., low-k dielectric material), such as SiOₓ (e.g., SiO₂). In further embodiments, the dipole-forming material 146 may be formed as stack of different dipole-forming materials within unfilled portions of the first trench 116 (FIG. 1J) and the second trenches 132 (FIG. 1J). The stack of different dipole-forming materials may be configured to form a gradient of effective fixed charge across an overall thickness of the dipole-forming material 146. Various potential configurations for the dipole-forming material 146 are described in further detail below with reference to FIGS. 2A through 2D.

Referring next to FIG. 1L, further processing may be effectuated on or with the microelectronic device structure 100 following the process stage described with reference to FIG. 1J to form a second assembly 147 including the microelectronic device structure 100 and coupled with a multi-storage node structure 160. The DL structures 108 may vertically overlie and be coupled to the vertical channel access devices 134 of the microelectronic device structure 100, and the multi-storage node structure 160 may be vertically underlie and include storage node devices 166 coupled to the vertical channel access devices 134 of the microelectronic device structure 100. Various features of the microelectronic device are described in further detail below.

The DL structures 108 may be formed using any suitable processing. For example, as previously described herein with reference to FIGS. 1A-1J, the DL structures 108 may be formed prior to the formation of the vertical channel access devices 134. In additional embodiments, such as embodiments wherein the microelectronic device structure 100 at the process stage of FIG. 1A is formed to include an etch stop material (e.g., SiGe) in place of the DL structures 108, the DL structures 108 may be formed after the formation of the vertical channel access devices 134 and the dipole-forming material 146. For example, following the processing stage of FIG. 1J (and, optionally, following after formation and/or attachment of the multi-storage node structure 160 to the microelectronic device structure 100) the microelectronic device structure 100 may be vertically inverted, the etch stop material (and a carrier structure associated therewith) may be removed, and then the DL structures 108 may be formed. The DL structures 108 are coupled to the first doped regions 102 (e.g., drain regions) of the semiconductor pillars 133 of the vertical channel access devices 134.

As shown in FIG. 1L, a dielectric liner material 150 may be formed on or over the DL structures 108 and a shield structure 148 (e.g., DL shield structure) may be formed on or over the dielectric liner material 150. The shield structure 148 may cover an upper surface of the dielectric liner material 150. As a result, in some embodiments, the shield structure 148 includes projections extending vertically downward between horizontally neighboring structures within the DL structures 108. The shield structure 148 (e.g., upper shielding plate, top shielding plate) may be configured and positioned to shield (e.g., protect) features (e.g., structures, materials, devices, digit lines) of the microelectronic device from undesirable electrical interference (e.g., electromagnetic interference (EMI)).

The shield structure 148 may be formed of and include conductive material. In some embodiments, the shield structure 148 is formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shield structure 148 may be formed of and include tungsten (W). The shield structure 148 may be substantially homogeneous, or the shield structure 148 may be heterogeneous. If the shield structure 148 is heterogeneous, amounts of one or more elements included in the shield structure 148 may vary stepwise (e.g., change abruptly), or may vary continuously (e.g., change progressively, such as linearly, parabolically) throughout different portions of the shield structure 148. The shield structure 148 may, for example, be formed of and include a stack of at least two different conductive materials.

Still referring to FIG. 1L, an insulative material 152 may be formed over and on or over the shield structure 148. The insulative material 152 may be formed to have an at least substantially planar upper surface 154. In one or more embodiments, the insulative material 152 is formed of and includes a dielectric oxide material, such as SiOₓ (e.g., SiO₂). The insulative material 152 may be substantially homogeneous, or the insulative material 152 may be heterogeneous. As is discussed in greater detail below, in some embodiments, the insulative material 152 of the second assembly 147 may be utilized to bond the second assembly 147 to another structure by dielectric-to-dielectric bonding, such as an oxide-to-oxide bonding, as described in further detail below with reference to FIG. 1M.

Still referring to FIG. 1L, the second assembly 147 may be formed to further include redistribution material (RDM) structures 145 that may, for example, facilitate a horizontal arrangement (e.g., a hexagonal close packed arrangement) of the storage node devices 166 (e.g., capacitors) (described in further detail below) of the multi-storage node structure 160 that is different than a horizontal arrangement of the semiconductor pillars 133 of the vertical channel access devices 134 of the microelectronic device structure 100, while still coupling the vertical channel access devices 134 to the storage node devices 166. The RDM structures 145 may be formed of and include conductive material, such as one or more of W, Ru, Mo, and TiN_{y}.

As previously mentioned, the multi-storage node structure 160 includes multiple storage node devices 166 (e.g., capacitors) may be formed on or over the RDM structures 145 to form a second assembly 147, the second assembly 147 including the first assembly 103 and the multi-storage node structure 160. The storage node devices 166 may be in electrical contact with the RDM structures 145, and, hence, with the vertical channel access devices 134. The storage node devices 166 may be coupled to the vertical channel access devices 134 by way of at least the RDM structures 145 to form memory cells 141 (e.g., DRAM cells).

Each memory cell 141 may individually include one of the vertical channel access devices 134, one of the storage node devices 166, and one of the RDM structures 145 extending from and between the one of the vertical channel access devices 134 and the one of the storage node devices 166. The storage node devices 166 may individually be formed and configured to store a charge representative of a programmable logic state of the memory cell 141 including the storage node device 166.

In some embodiments, the storage node devices 166 include capacitors. During use and operation, a charged capacitor may represent a first logic state, such as a logic 1; and an uncharged capacitor may represent a second logic state, such as a logic 0. Each of the storage node devices 166 may, for example, be formed to include a first electrode 162 (e.g., a bottom electrode), a second electrode 163 (e.g., a top electrode), and a dielectric material 164 between the first electrode 162 and the second electrode 163. For instance, each of the storage node devices 166 may include a metal-insulator-metal (MIM) capacitor. As another example, each of the storage node devices 166 may include a metal-insulator-semiconductor (MIS) capacitor. The collection of memory cells 141 may form a memory array.

The multi-storage node structure 160 may further include a conductive material 161 formed between neighboring storage node devices 166. The conductive material 161 may substantially cover and surround the storage node devices 166. The second electrode 163 of the storage node devices 166 may be operatively positioned (e.g., embedded) within the conductive material 161. The conductive material 161 may include any of the conductive materials described herein. For instance, the conductive material 161 may include polysilicon or conductively-doped silicon germanium (SiGe).

Still referring to FIG. 1L, a cell plate 165 may be formed on and over the multi-storage node structure 160 of the second assembly 147. For instance, the cell plate 165 may be formed on and over the conductive material 161. The cell plate 165 may include any of the conductive materials described herein. For instance, the cell plate 165 may include a tungsten (W). A carrier structure 169 (e.g., a carrier wafer) may be formed on or attached to the multi-storage node structure 160 of the second assembly 147. The carrier structure 169 may include a second base structure 168 and an insulative material 167 on or over the second base structure 168. In some embodiments, the insulative material 167 is formed of and includes a dielectric oxide material, such as SiOₓ (e.g., SiO₂). The insulative material 167 may be substantially homogeneous, or the insulative material 167 may be heterogeneous.

The second base structure 168 may include a base material or construction upon which additional features (e.g., materials, structures, devices) of the formed. In some embodiments, the second base structure 168 comprises a wafer. The second base structure 168 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (one or more of borosilicate glass (BSP), phosphosilicate glass (PSG), fluorosilicate glass (FSG), borophosphosilicate glass (BPSG), aluminosilicate glass, an alkaline earth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α-Al₂O₃), and silicon carbide). By way of non-limiting example, the second base structure 168 may comprise a semiconductor wafer (e.g., a silicon wafer), a glass wafer, or a ceramic wafer. The second base structure 168 may include one or more materials, structures, and/or regions formed therein and/or thereon.

Referring next to FIG. 1M, a control circuitry structure 180 may be attached (e.g., bonded, such as at least dielectric-to-dielectric bonded) to the second assembly 147 to form a microelectronic device 170 (e.g., a memory device, such as a DRAM device) of the disclosure. Circuitry of the control circuitry structure 180 may be coupled to various features (e.g., the DL structures 108, the memory cells 141) of the second assembly 147, as indicated in FIG. 1M by a dashed line 182.

In some implementations, the control circuitry structure 180 includes complementary metal-oxide-semiconductor (CMOS) circuitry. As a non-limiting example, the control circuitry structure 180 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry.

Referring again briefly to FIG. 1K, as previously mentioned the dipole-forming material 146 may be formed to have various configurations within the horizontal areas of the first trenches 116 (FIG. 1J) and the second trenches 132 (FIG. 1J). For example, FIGS. 2A-2D are enlarged views of the area labeled “W” in FIG. 1K, showing different configurations for the dipole-forming material 146 within a horizontal area of one of the second trenches 132, in accordance with various embodiments of the disclosure. While FIGS. 2A-2D depict a different potential configurations of the dipole-forming material 146 within the horizontal area of an individual second trench 132, the configurations shown in FIGS. 2A-2D may be employed in horizontal area(s) of one or more others of the second trenches 132 (FIG. 1J) and/or in one or more in horizontal area(s) of one or more of the first trenches 116 (FIG. 1J) (while accounting for the different features associated with the first trenches 116 (FIG. 1J) relative to those associated with the second trenches 132 (FIG. 1J)).

Referring to FIG. 2A, in one implementation, the dipole-forming material 146 is configured to substantially fill portions of the second trenches 132 vertically overlying the dielectric material 144 and horizontally interposed between opposing portions of the second dielectric liner 136. The dipole-forming material 146 may be configured as a single, bulk fill material. In addition, an upper boundary of the dipole-forming material 146 may be substantially coplanar (e.g., substantially flush) with upper boundaries of the second doped regions 106 (e.g., the source regions) of the semiconductor pillars 133 horizontally adjacent thereto. The dipole-forming material 146 within horizontal areas of the second trenches 132 may be substantially homogeneous. In another implementation, the dipole-forming material 146 is heterogeneous.

Still referring to FIG. 2A, in additional embodiments, an upper boundary of the dipole-forming material 146 formed within the second trench 132 is substantially coplanar (e.g., substantially flush) with upper boundaries of the second doped regions 106 (e.g., the source region) of the semiconductor pillars 133 horizontally adjacent thereto, as indicated by dashed line 202. Instead, the upper boundary (e.g., upper surface, top surface) of the dipole-forming material 146 may be configured to be vertically offset by a distance D below the upper boundaries of the second doped regions 106 (e.g., the source regions) of the semiconductor pillars 133. For example, the upper boundary of dipole-forming material 146 may be approximately 5 nm to 20 nm below the upper boundaries of second doped regions 106 of the semiconductor pillars 133. Additional material (e.g., additional dielectric material, such as a low-k dielectric material) may be used to fill a remainder of the second trench 132 in the instance the upper boundary of the dipole-forming material 146 is vertically offset below the upper boundaries of the second doped regions 106.

Referring to next FIG. 2B, in additional embodiments, the dipole-forming material 146 is formed (e.g., conformally deposited) within the second trench 132. Inner surfaces of the dipole-forming material 146 may define an inner cavity 206 comprising a portion of the second trench 132 remaining following the formation of the dipole-forming material 146. In some embodiments, the dipole-forming material 146 is formed to have a thickness within a range of from about 1 nanometer (nm) to about 10 nm, such as from about 2 nm to about 8 nm, or from about 2 nm to about 5 nm. Following the formation of the dipole-forming material 146, the inner cavity 206 defined thereby may be filled (e.g., substantially filled) with additional material 207. The additional material 207 may be a dielectric material, such as a low-k dielectric material (e.g., SiOₓ, such as SiO₂).

Referring to next to FIG. 2C, in additional embodiments, the dipole-forming material 146 within the second trenches 132 may be configured to have a first width 208 in the X-direction between opposing portions of the second dielectric liner 136 that is larger than a second width 210 in the X-direction between additional opposing portions of the second dielectric liner 136 vertically underlying an upper boundary of the dielectric material 144. In this configuration, the dipole-forming material 146 is positioned relatively horizontally closer to the semiconductor pillars 133 of the vertical channel access devices 134 in the X-direction than are the gate electrodes 142 of the vertical channel access devices 134. Outer sidewalls of the dipole-forming material 146 are horizontally offset from the sidewalls (e.g., inner sidewalls and outer sidewalls) of the gate electrodes 142. In one implementation, an upper boundary of the dipole-forming material 146 is substantially coplanar (e.g., substantially flush) with upper boundaries of the second doped regions 106 (e.g., the source regions) of the semiconductor pillars 133 horizontally adjacent thereto. In another implementation, the upper boundary of the dipole-forming material 146 is vertically offset from (e.g., vertically underlies) the upper boundaries of the second doped regions 106 (e.g., the source regions) of the semiconductor pillars 133 horizontally adjacent thereto.

Referring next to FIG. 2D, in further embodiments, the dipole-forming material 146 may comprise multiple, different materials vertically stacked relative to one another to substantially fill portions of the second trenches 132 vertically overlying the dielectric material 144 and horizontally interposed between opposing portions of the second dielectric liner 136. For example, the dipole-forming material 146 within a horizontal area of an individual second trench 132 may be formed to include an additional dipole-forming material, namely, a first dipole-forming material 146A on or over the dielectric material 144, a second dipole-forming material 146B on or over the first dipole-forming material 146A, a third dipole-forming material 146C on or over the second dipole-forming material 146B, and a fourth dipole-forming material 146D on or over the third dipole-forming material 146C. At least some of the first dipole-forming material 146A, the second dipole-forming material 146B, the third dipole-forming material 146C, and the fourth dipole-forming material 146D may have a different material composition than at least some others of the first dipole-forming material 146A, the second dipole-forming material 146B, the third dipole-forming material 146C, and the fourth dipole-forming material 146D. For example, one or more of the first dipole-forming material 146A, the second dipole-forming material 146B, the third dipole-forming material 146C, and the fourth dipole-forming material 146D may comprise a first high-k dielectric material, and one or more others of the first dipole-forming material 146A, the second dipole-forming material 146B, the third dipole-forming material 146C, and the fourth dipole-forming material 146D may comprise a second, different high-k dielectric material. The first dipole-forming material 146A, the second dipole-forming material 146B, the third dipole-forming material 146C, and the fourth dipole-forming material 146D may respectively be configured to provide a vertical gradient of effective fixed charge at the second interfaces 155 of the overall dipole-forming material 146 and the second dielectric liner 136.

The number, thicknesses, and configurations of the different dipole-forming materials 146A, 146B, 146C, 146D depicted in FIG. 2D is shown for illustrative purposes and may be varied as would be appreciated by one of ordinary skill in the art having the benefit of this disclosure. For example, the overall dipole-forming material 146 may include a stack of less than four (4) (e.g., three, two) different dipole-forming material materials, or may include a stack of more than four (4) different dipole-forming material materials.

In one implementation, an upper boundary of the dipole-forming material 146 (e.g., as defined by an upper boundary of the fourth dipole-forming material 146D thereof) is substantially coplanar (e.g., substantially flush) with upper boundaries of the second doped regions 106 (e.g., the source regions) of the semiconductor pillars 133 horizontally adjacent thereto. In another implementation, the upper boundary of the dipole-forming material 146 (e.g., as defined by an upper boundary of the fourth dipole-forming material 146D thereof) is vertically offset from (e.g., vertically underlies) the upper boundaries of the second doped regions 106 (e.g., the source regions) of the semiconductor pillars 133 horizontally adjacent thereto.

In accordance with embodiments of the disclosure, a microelectronic device includes a vertical channel access device that includes a semiconductor pillar. The semiconductor pillar includes a first doped region, a channel region vertically above the first doped region, and a second doped region vertically above the channel region. The vertical channel access device includes a gate electrode horizontally offset from and vertically overlapping the channel region of the semiconductor pillar and a gate dielectric material horizontally interposed between the gate electrode and the semiconductor pillar. The microelectronic device includes a dipole-forming material at a vertical position of the second doped region of the semiconductor pillar of the vertical channel access device, the dipole-forming material directly physically contacting the gate dielectric material and effectuating a fixed polarization effect at an interface of the gate dielectric material and the dipole-forming material.

In accordance with embodiments of the disclosure, a method of forming a microelectronic device includes forming vertical channel access devices horizontally separated from one another by a trench containing gate electrodes for the vertical channel access devices, and forming a dipole-forming material within the trench and vertically overlying the gate electrodes, the dipole-forming material in physical contact with sidewalls of a gate dielectric material of the vertical channel access devices and configured to effectuate a fixed polarization effect at interfaces of the gate dielectric material and the dipole-forming material.

In accordance with embodiments of the disclosure, a memory device includes a memory cell that includes a vertical channel access device. The vertical channel access device includes a channel region vertically interposed between the two source/drain regions, a gate electrode horizontally offset from and vertically overlapping the channel region, and a gate dielectric material horizontally interposed between the channel region and the gate electrode and vertically overlapping the channel region and at least part of the two source/drain regions. The memory cell including a storage node device vertically offset from and coupled to the vertical channel access device and the memory device including a dipole-forming material physically contacting a sidewall of the gate dielectric material of the vertical channel access device of the memory cell and substantially confined within a vertically extent of one of the two source/drain regions of the vertical channel access device of the memory cell, differences in electric properties of the dipole-forming material and the gate dielectric material effectuating a net positive charge at an interface of the dipole-forming material and the gate dielectric material.

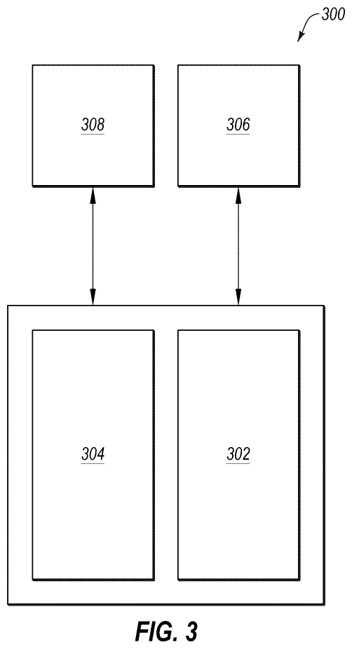

Microelectronic devices (e.g., the microelectronic device 170 (FIG. 1M)) in accordance with embodiments of the disclosure may be used in embodiments of electronic systems of the disclosure. For example, FIG. 3 is a block diagram illustrating an electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) material, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, a microelectronic device (e.g., the microelectronic device 170 (FIG. 1M)) previously described herein. The electronic system 300 may further include at least one electronic signal processor device 304 (often referred to as a “microprocessor”). The electronic signal processor device 304 may, optionally, comprise a microelectronic device (e.g., the microelectronic device 170 (FIG. 1M)) previously described herein. While the memory device 302 and the electronic signal processor device 304 are depicted as two (2) separate devices in FIG. 3, in additional embodiments, a single (e.g., only one) memory/processor device having the functionalities of the memory device 302 and the electronic signal processor device 304 is included in the electronic system 300. In such embodiments, the memory/processor device may include a microelectronic device (e.g., the microelectronic device 170 (FIG. 1M)) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure. Various modifications of the disclosure, in addition to those shown and described herein, such as alternate useful combinations of the elements and features described will become apparent to those skilled in the art from the description. Such modifications and embodiments also fall within the scope of the appended claims and equivalents.

What is claimed is:

1. A microelectronic device, comprising:
a vertical channel access device comprising:
a semiconductor pillar comprising:
a first doped region;
a channel region vertically above the first doped region; and
a second doped region vertically above the channel region;
a gate electrode horizontally offset from and vertically overlapping the channel region of the semiconductor pillar; and
gate dielectric material horizontally interposed between the gate electrode and the semiconductor pillar; and
a dipole-forming material at a vertical position of the second doped region of the semiconductor pillar of the vertical channel access device, the dipole-forming material directly physically contacting the gate dielectric material and effectuating a fixed polarization effect at an interface of the gate dielectric material and the dipole-forming material.

2. The microelectronic device of claim 1, wherein the dipole-forming material is configured to effectuate a net positive charge on a dipole-forming material side of the interface of the gate dielectric material and the dipole-forming material.

3. The microelectronic device of claim 1, wherein an effective fixed charge density at the interface of the gate dielectric material and the dipole-forming material is within a range of from about 1×10¹¹ charges (C) per square centimeter (cm²) (C/cm²) to about 1×10¹⁴ C/cm².

4. The microelectronic device of claim 1, wherein:
the gate dielectric material of the vertical channel access device comprises a low-k dielectric material; and
the dipole-forming material comprises a high-k dielectric material.

5. The microelectronic device of claim 4, wherein:
the gate dielectric material of the vertical channel access device comprises silicon oxide; and
the dipole-forming material comprises one or more of lanthanum oxide, zirconium oxide, aluminum oxide, titanium oxide, and hafnium oxide.

6. The microelectronic device of claim 1, wherein a top surface of the dipole-forming material is substantially flush with an upper surface of the second doped region of the semiconductor pillar of the vertical channel access device.

7. The microelectronic device of claim 1, wherein a top surface of the dipole-forming material vertically underlies an upper surface of the second doped region of the semiconductor pillar of the vertical channel access device.

8. The microelectronic device of claim 1, further comprising additional dielectric material having sidewalls and a lower surface respectively in physical contact with the dipole-forming material.

9. The microelectronic device of claim 1, wherein the dipole-forming material is substantially homogeneous.

10. The microelectronic device of claim 1, wherein the dipole-forming material is heterogeneous.

11. The microelectronic device of claim 1, further comprising:
a shield gate structure horizontally neighboring the vertical channel access device and at least partially vertically overlapping the gate electrode of the vertical channel access device;
a dielectric liner material horizontally interposed between the shield gate structure and the semiconductor pillar of the vertical channel access device; and
additional dipole-forming material at the vertical position of the second doped region of the semiconductor pillar of the vertical channel access device, the additional dipole-forming material directly physically contacting the dielectric liner material and effectuating an additional fixed polarization effect at an additional interface of the dielectric liner material and the additional dipole-forming material.

12. The microelectronic device of claim 11, wherein:
a material composition of the dielectric liner material is substantially the same as that of the gate dielectric material of the vertical channel access device; and
a material composition of the additional dipole-forming material is substantially the same as that of the dipole-forming material.

13. A method of forming a microelectronic device, comprising:
forming vertical channel access devices horizontally separated from one another by a trench containing gate electrodes for the vertical channel access devices; and
forming a dipole-forming material within the trench and vertically overlying the gate electrodes, the dipole-forming material in physical contact with sidewalls of a gate dielectric material of the vertical channel access devices and configured to effectuate a fixed polarization effect at interfaces of the gate dielectric material and the dipole-forming material.

14. The method of claim 13, further comprising forming a dielectric barrier material within the trench and over the gate electrodes for the vertical channel access devices prior to forming the dipole-forming material within the trench, the dipole-forming material physically contacting an upper surface of the dielectric barrier material upon formation.

15. The method of claim 13, further comprising:
selecting the gate dielectric material of the vertical channel access devices to comprise a low-k dielectric oxide material; and
selecting the dipole-forming material to comprise a high-k dielectric oxide material.

16. The method of claim 13, further comprising forming the dipole-forming material to at least partially vertically overlap source regions of the vertical channel access devices.

17. The method of claim 13, further comprising forming an additional dipole-forming material within an additional trench horizontally neighboring one of the vertical channel access devices and containing a shield gate structure at a vertical elevation of the gate electrodes of the vertical channel access devices and a dielectric liner material horizontally interposed between the shield gate structure and the one of the vertical channel access devices, the additional dipole-forming material in physical contact with sidewalls of the dielectric liner material and configured to effectuate an additional fixed polarization effect at additional interfaces of the dielectric liner material and the additional dipole-forming material.

18. A memory device, comprising:
a memory cell comprising:
a vertical channel access device comprising:
a channel region vertically interposed between two source/drain regions;
a gate electrode horizontally offset from and vertically overlapping the channel region; and
a gate dielectric material horizontally interposed between the channel region and the gate electrode and vertically overlapping the channel region and at least part of the two source/drain regions;
a storage node device vertically offset from and coupled to the vertical channel access device; and
a dipole-forming material physically contacting a sidewall of the gate dielectric material of the vertical channel access device of the memory cell and substantially confined within a vertically extent of one of the two source/drain regions of the vertical channel access device of the memory cell, differences in electric properties of the dipole-forming material and the gate dielectric material effectuating a net positive charge at an interface of the dipole-forming material and the gate dielectric material.

19. The memory device of claim 18, wherein:
the gate dielectric material comprises silicon oxide; and
the dipole-forming material comprises lanthanum oxide.

20. The memory device of claim 18, wherein the memory cell comprises a dynamic random-access memory (DRAM) cell.
